(19) United States
(12) Patent Application Publication
(10) Pub. No.: US 2016/0218312 A1
(43) Pub. Date: Jul. 28, 2016

(54) DISPLAY DEVICE

(71) Applicant: SAMSUNG DISPLAY CO., LTD., Yongin-si (KR)

(72) Inventor: Sein CHANG, Suwon-si (KR)

(21) Appl. No.: 14/851,326

(22) Filed: Sep. 11, 2015

(30) Foreign Application Priority Data
Jan. 28, 2015 (KR) 10-2015-0013641

(51) Int. Cl. H01L 51/52

(52) U.S. Cl. CPC H01L 51/525; H01L 51/5246

(57) ABSTRACT

A display device includes a display panel including a display area and a pad area, a window opposite to the display panel, the window covering the display area and the pad area of the display panel, a spacer in the pad area and having elasticity, and a first adhesive layer between the window and the display panel, the first adhesive layer being on at least a portion of the spacer.

### CROSS-REFERENCE TO RELATED APPLICATION

Korean Patent Application No. 10-2015-0013641, filed on Jan. 28, 2015, in the Korean Intellectual Property Office, and entitled: “Display Device,” is incorporated by reference herein in its entirety.

### BACKGROUND

1. Field

Embodiments relate to a display device including a spacer disposed in a pad area and having elasticity.

2. Description of the Related Art

In general, flat panel display (FPD) devices, e.g., liquid crystal display (LCD) devices or organic light emitting diode (OLED) display devices, include a plurality of pairs of electric field generating electrodes and electro-optical active layers interposed therebetween. A LCD device includes a liquid crystal layer as an electro-optical active layer, and an OLED display device includes an organic light emitting layer as an electro-optical active layer.

A display device commonly has a driving chip or a flexible printed circuit board (FPCB) mounted thereon in an edge portion (hereinafter, referred to as a pad area) of a display panel. The pad area is an area in which an encapsulation substrate is removed, and a first adhesive layer for adhering a display panel and a window to one another is positioned in an empty space between the pad area and the window.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

According to an exemplary embodiment, a display device includes a display panel including a display area and a pad area; and a window disposed opposite to the display panel, and covering the display area and the pad area; a spacer disposed in the pad area and having elasticity; and a first adhesive layer disposed between the window and the display panel and coated on at least a portion of the spacer.

The display device may further include a circuit member disposed on the pad area.

The spacer may be disposed adjacently to at least an end of the circuit member.

A height of the spacer may be less than a gap between the pad area and the window.

The spacer may include: a cushion layer having elasticity; and a coating layer encapsulating the cushion layer.

The spacer may further include a second adhesive layer disposed between the display panel and the coating layer.

A hardness of the coating layer may be greater than a hardness of the first adhesive layer.

A shore hardness of the coating layer may be in a range of about 20 to about 80.

A hardness of the cushion layer may be less than a hardness of the first adhesive layer.

A viscosity of the cushion layer may be in a range of about one centipoise (cps) to about 100,000 cps.

The coating layer may include silicon rubber.

The cushion layer may include at least one of a silicon gel, a silicon fluid, a silicon resin, and a liquid epoxy resin.

The circuit member may be at least one of an integrated circuit chip and a flexible printed circuit board (FPCB).

A cross section of the spacer may have one of a semi-circular shape and a polygonal shape.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic perspective view of an organic light emitting diode (OLED) display device according to a first exemplary embodiment;

FIG. 2 illustrates a cross-sectional view taken along line I-I′ of FIG. 1;

FIG. 3 illustrates a cross-sectional view taken along line II-II′ of FIG. 1;

FIG. 4 illustrates a schematic plan view of a pixel of an OLED display device according to a first exemplary embodiment;

FIG. 5 illustrates a cross-sectional view taken along line A-A′ of FIG. 4;

FIG. 6 illustrates a schematic cross-sectional view of an OLED display device according to a second exemplary embodiment; and

FIG. 7 illustrates a schematic cross-sectional view of an OLED display device according to a third exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when an element (e.g., a layer) is referred to as being “on” another element or substrate, it can be directly on the other element or substrate, or intervening layers may also be present. In addition, it will also be understood that when an element is referred to as being “between” two elements, it can be the only element between the two elements, or one or more intervening elements may also be present. Further, when an element is referred to as being “connected” to another element, the element is “directly connected” to the other element, or “electrically connected” to the other element with one or more intervening elements interposed therebetween. Like reference numerals refer to like elements throughout.

All terminologies used herein are merely used to describe embodiments and may be modified according to the relevant art and the intention of an applicant. Therefore, the terms used herein should be interpreted as having a meaning that is consistent with their meanings in the context of the present disclosure, and is not intended to limit. As used herein, the singular forms “a,” “an,” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

In addition, although the accompanying drawings illustrate an active matrix organic light emitting diode (AMOLED) display device having a 2Tr-1Cap structure in which a single pixel includes two thin film transistors (TFTs) and a single capacitor, the type of an organic light emitting diode (OLED) display device according to an exemplary embodiment is not limited thereto. Accordingly, in an OLED display device according to an exemplary embodiment, the number of TFTs, capacitors, and wirings is not limited. As used herein, the term “pixel” refers to a minimum unit for displaying an image, and an OLED display device may display an image through a plurality of pixels.

Unless otherwise defined, all terms used herein (including technical and scientific terms) have the same meaning as commonly understood by those skilled in the art. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Meanwhile, the term “substrate” used herein refers to a first substrate unless otherwise indicated.

Further, it will be assumed that a display device according to an exemplary embodiment is an OLED display device including an organic light emitting layer. However, a display device according to an exemplary embodiment may also use a liquid crystal display (LCD) device, a plasma display panel (PDP) device, or a field emission display (FED) device.

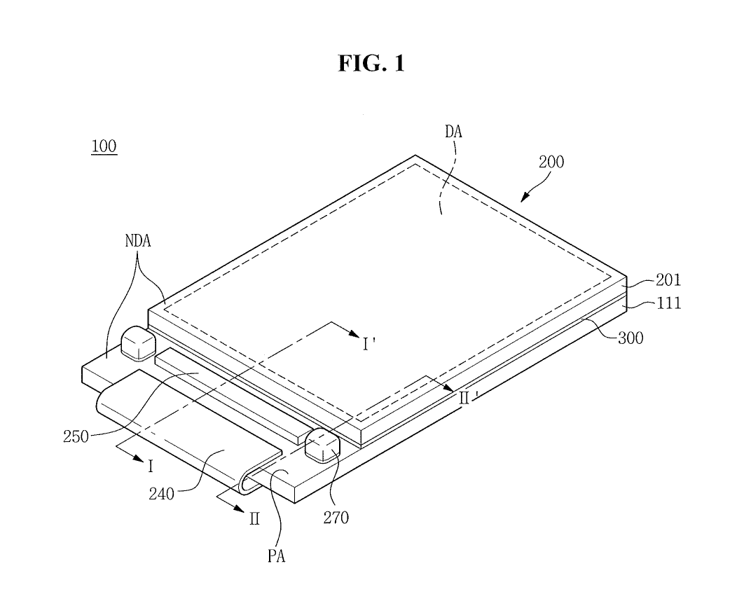

Hereinafter, an OLED display device according to a first exemplary embodiment will be described with reference to FIGS. 1 through 5.

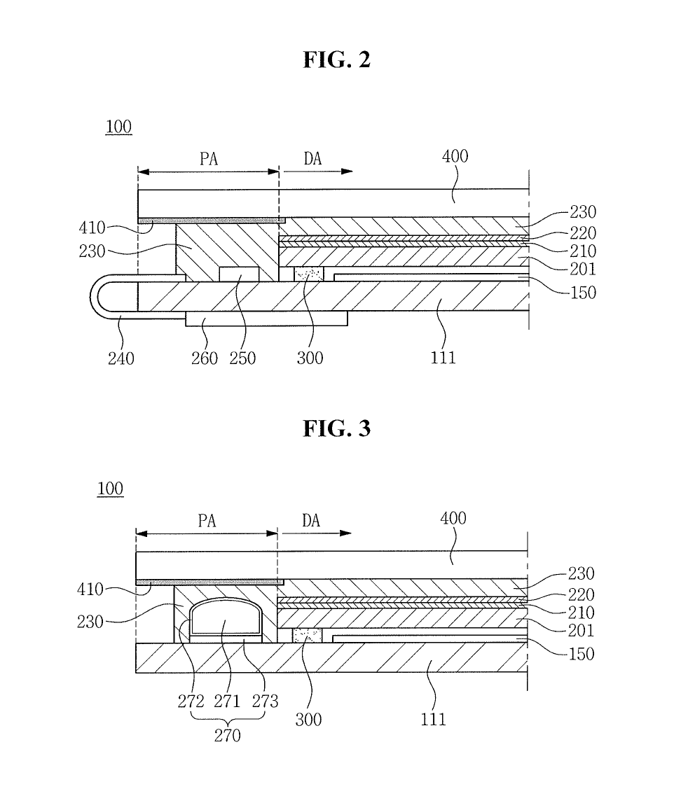

FIG. 1 is a perspective view schematically illustrating an OLED display device according to a first exemplary embodiment. FIG. 2 is a cross-sectional view taken along line I-I′ of FIG. 1, and FIG. 3 is a cross-sectional view taken along line II-II′ of FIG. 1.

Referring to FIGS. 1 through 3, an OLED display device 100 according to a first exemplary embodiment may include a display panel 200, a first adhesive layer 230, a connection portion 240, a driving chip 250, a printed circuit board (PCB) 260, a spacer 270, a window 400, and a black matrix 410.

The display panel 200, i.e., a panel displaying an image, may be an OLED display panel. Alternatively, the display panel 200 may be one of a LCD panel, an electrophoretic display (EPD) panel, a light emitting diode (LED) display panel, an inorganic electroluminescent (EL) display panel, a FED panel, a surface-conduction electron-emitter display (SED) panel, a PDP, and a cathode ray tube (CRT) display panel. However, the aforementioned types of the display panel are only given by way of example, and all types of display panels including those commercialized and currently available or those to be further developed in accordance with advances in technology may be used as the display panel 200 according to an exemplary embodiment.

The display panel 200 may include a first substrate 111, a second substrate 201 disposed opposite to the first substrate 111, a display portion 150, a sealant 300, a touch portion 210, and a polarizing plate 220. However, the configuration of the display panel 200 is not limited thereto. Accordingly, the first substrate 100 may also be sealed by a sealing film, or the like, other than the second substrate 201.

The first substrate 111 may include a display area DA, in which an image is displayed by light emission, and a non-display area NDA disposed along an edge portion of the display area DA. The display area DA of the first substrate 111 may include a plurality of pixels formed therein to display images. The display portion 150 may be disposed in the display area DA.

The non-display area NDA may include a pad area PA in which a plurality of conductive pads are formed. The conductive pads may receive an external signal supplied thereto which allows an OLED element to emit light to transmit the external signal to the OLED element. The pad area PA may include at least the driving chip 250 formed thereon.

The first substrate 111 may be formed of a transparent glass material, e.g., mainly composed of silicon oxide (SiO₂). However, the material forming the first substrate 111 is not limited thereto, and may be formed of a transparent plastic material.

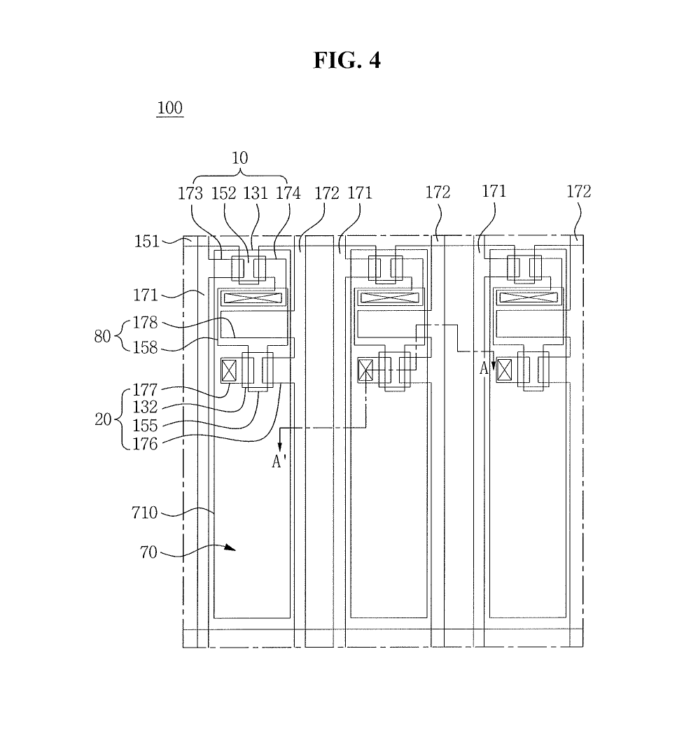

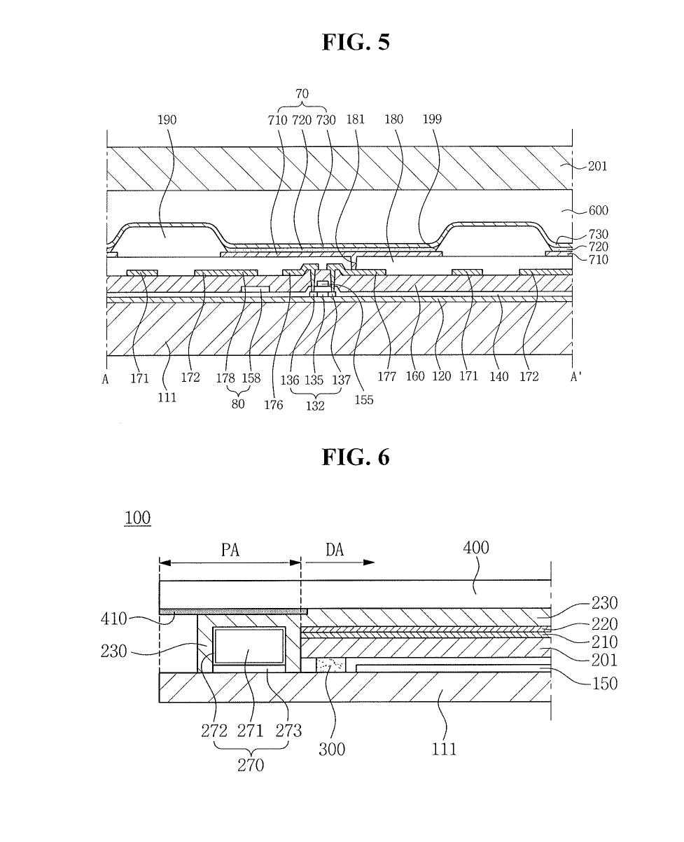

The display portion 150 may be formed on the first substrate 111, and may be connected to the driving chip 250. The display portion 150 may include an OLED element, a thin film transistor (TFT) for driving the OLED element, a wiring, and the like. A description pertaining to the display portion 150 will be provided further with reference to FIGS. 4 and 5. Aside from the OLED element, any element able to configure the display device may be included in the display portion 150.

The second substrate 201 may be disposed opposite to the first substrate 111, and may be laminated onto the first substrate 111 while having the sealant 300 therebetween. The second substrate 201 may cover and protect the display portion 150. The second substrate 201 may use a glass substrate, a transparent synthetic resin film, e.g., an acrylic resin, or a metal substrate. For example, the second substrate 201 may be formed using one of, e.g., a polyethylene (PE) film, a polypropylene (PP) film, polyamide (PA) film, a polyacetal or polyoxymethylene (POM) film, a poly(methyl methacrylate) (PMMA) film, a polybutylene terephthalate (PBT) film, a polycarbonate (PC) film, a cellulose film, and a moisture-proof cellophane.

The second substrate 201 may have an area smaller than that of the first substrate 111. Accordingly, the pad area PA of the first substrate 111 may be exposed through the second substrate 201. For example, the second substrate 201 may cover the display area DA of the first substrate 111, such that the pad area PA of the first substrate 111 may be exposed, e.g., not covered, by the second substrate 201.

The sealant 300 may be disposed between the first and second substrates 111 and 201. The sealant 300 may use a commonly used material, e.g., a sealing glass frit.

The touch portion 210 may be disposed on the second substrate 201, corresponding to, e.g., overlapping, the display area DA of the first substrate 111. The touch portion 210 may include first and second electrodes intersecting one another. The first and second electrodes may be patterned, directly on the second substrate 201, in a plurality of rows of a matrix form to thereby be formed in an on-cell type manner. The first and second electrodes may correspond to a touch sensor pattern. In addition, the touch portion 210 may be disposed on the second substrate 201, as a separately provided touch panel.

The touch portion 210 may recognize a touch input from a touch unit, e.g., a pen or a finger of a user, to transmit a signal corresponding to a position at which the touch input is performed. The touch portion 210 may be used as an input unit with respect to the OLED display device 100, and may be provided in a resistive or capacitive manner.

The window 400 may be formed of a transparent material, e.g., glass or resin, and may serve to protect the display panel 200 such that the display panel 200 is not damaged due to external impacts applied thereto. For example, the window 400 may be disposed on the touch portion 210, and may cover the display area DA and the pad area PA. The window 400 may be adhered to the second substrate 201 using the first adhesive layer 230 therebetween. The first adhesive layer 230 may be, for example, a resin. The window 400 may be formed to be greater than the display panel 200; however, the size of the window 400 is not limited thereto, and the window 400 may be formed to have substantially the same size as that of the display panel 200.

The black matrix 410 may be disposed on a portion of the window 400 corresponding to, e.g., overlapping, the pad area PA. The black matrix 410 may be a light shielding film, and may include a printing material used to obstruct, e.g., block, visibility of a pattern disposed below the window 400. The printing material may be formed of a black printing material; however, the color of the printing material may change based on a design of a device to be provided. Meanwhile, the black matrix 410 may include a light-absorbing material, e.g., chromium (Cr).

The polarizing plate 220 may be disposed between the window 400 and the touch portion 210. The polarizing plate 200 may prevent reflection of external light.

The first adhesive layer 230 may be disposed between the window 400 and the touch portion 210, and between the pad area PA of the first substrate 111 and the window 400. The first adhesive layer 230 may serve to enhance luminance, transmissivity, reflectivity, and visibility of the OLED display device 100. The first adhesive layer 230 may be coated on the pad area PA, in which a circuit member, e.g., the driving chip 250, and the like, is disposed. The first adhesive layer 230 may prevent an air gap from being formed between the window 400 and the display panel 200, and may prevent penetration of foreign materials, e.g., dust, thereto. The first adhesive layer 230 may be a photocurable resin.

The driving chip 250 may generate a driving signal for driving the display panel 200 in response to an external signal. The external signal may be a signal supplied from the PCB 260, and may include an image signal, various types of control signals, a driving voltage, and the like. The driving chip 250 may be an integrated circuit chip, e.g., a driving integrated circuit (IC).

The driving chip 250 may be directly mounted on the non-display area NDA of the display panel 200 using an anisotropic conductive film (ACF) in a chip-on-glass (COG) manner. Meanwhile, the driving chip 250 may not necessarily be formed in the non-display area NDA, and may also be omitted. In addition, the driving chip 250 may be mounted on a FPCB in a chip-on-film (COF) manner. That is, a tape-carrier-package (TCP) in which the driving chip 250 is mounted on a film in a chip form may be applied to the OLED display device 100.

The PCB 260 may be a circuit board applying a driving signal directly to the display panel 200 or supplying an external signal generating the driving signal. The PCB 260 may include a timing controller generating a control signal for driving the display panel 200, a power voltage generating unit generating a power voltage, and the like.

The PCB 260 may be disposed on a surface of the display panel 200. More particularly, the PCB 260 may be disposed on a rear surface of the display panel 200, e.g., the PCB 260 and the driving chip 250 may be on opposite surfaces of the first substrate 111. In general, since the display panel 200 displays an image on a front surface of the display panel 200, i.e., a surface facing the window 400, the rear surface of the display panel 200 may be an area obscured to a user. Accordingly, in order to maximize spatial efficiency and hide an element unnecessary to be viewed to a user, the PCB 260 may be disposed on the rear surface of the display panel 200. However, the disposition of the PCB 260 is provided by way of example, and the PCB 260 may be disposed on a side surface of the display panel 200 as necessary, and the PCB and the FPCB may also be integrated.

The connection portion 240 may be connected to the pad area PA of the display panel 200. The connection portion 240 may be electrically connected to the display panel 200 and the PCB 260 to provide an electric connection therebetween. The connection portion 240 may be a FPCB. In addition, the connection portion 240 may be provided in a COF manner or a TCP manner in which an integrated circuit chip is included.

Although not illustrated, the connection portion 240 may include a base film and a wiring pattern disposed on the base film when viewed in a cross-sectional view, and may further include a cover film disposed on the wiring pattern. The base film and the cover film may be formed of a material exhibiting high flexibility, an insulation property, and thermal resistance. For example, the base film and the cover film may be formed of polyimide; however, the material forming the base film and the cover film is not limited thereto. The wiring pattern may be disposed between the base film and the cover film. The wiring pattern may serve to transmit a predetermined electric signal. The wiring pattern may be formed of a metal material, e.g., copper (Cu), and a surface of the wiring pattern formed of Cu may include, e.g., tin (Sn), silver (Ag), nickel (Ni), or the like, plated thereon. The manner of forming the wiring pattern may include a casting manner, a laminating manner, an electroplating manner, and the like, and the wiring pattern may be formed in various other manners.

The spacer 270 may be disposed on the pad area PA and may have elasticity, e.g., the spacer 270 may be disposed on the first substrate 111 in pad area PA. The spacer 270 may be disposed adjacently to at least an end of a circuit member. The circuit member may be at least one of the driving chip 250 and the connection portion 240. The first adhesive layer 230 may be coated on at least a portion of the spacer 270, and a height of the spacer 270 may be less than a gap between the pad area PA and the window 400, e.g., a height of the spacer 270 may be smaller than a gap between the first substrate 111 and the window 400. For example, as illustrated in FIG. 3, the first adhesive layer 230 may cover the top of the spacer 270, such that the first adhesive layer 230 fills a space between the top of the spacer 270 and the black matric 410. The spacer 270 may be a polymer or rubber having elasticity. As such, the spacer 270, having elasticity, may be disposed on the pad area PA, thereby absorbing external impacts and preventing damage thereto even in a case in which the black matrix 410 or the polarizing plate 220, which is pressed by external forces, comes in contact with the spacer 270.

Meanwhile, the spacer 270 may be formed of a single polymer having elasticity as described above, and may include a cushion layer 271 and a coating layer 272, as illustrated in FIG. 3. In detail, the spacer 270 may include the cushion layer 271 having elasticity and the coating layer 272 encapsulating the cushion layer 271.

The cushion layer 271 may include at least one of a silicon gel, a silicon fluid, a silicon resin, and a liquid epoxy resin. A viscosity of the cushion layer 271 may be in a range of about one centipoise (cps) to about 100,000 cps, and a hardness of the cushion layer 271 may be less than that of the first adhesive layer 230. That is, the cushion layer 271 may be manufactured in a liquid type or a gel type, thus having fluidity. Accordingly, due to the cushion layer 271, the spacer 270 may have elasticity.

The coating layer 272 may encapsulate the cushion layer 271, and may maintain a predetermined shape of the cushion layer 271. The coating layer 272 may include silicon rubber. A hardness of the coating layer 272 may be greater than that of the first adhesive layer 230, and a shore hardness of the coating layer 272 may be in a range of about 20 to about 80. As such, the cushion layer 271 may impart elasticity to the spacer 270, and the coating layer 272 may maintain a predetermined shape of the spacer 270.

Meanwhile, the spacer 270 may further include a second adhesive layer 273 disposed between the display panel 200 and the coating layer 272. The second adhesive layer 273 may adhere the spacer 270 to the display panel 200. For example, the second adhesive layer 273 may be a double-sided tape.

Hereinafter, a pixel of the display portion 150 will be described with reference to FIGS. 4 and 5. FIG. 4 is a plan view of a pixel of the OLED display device 100, and FIG. 5 is a cross-sectional view taken along line A-A′ of FIG. 4.

Referring to FIGS. 4 and 5, an AMOLED display device having a 2Tr-1Cap structure in which each pixel in the display area DA of FIG. 1 includes two TFTs, i.e., a switching TFT 10 and a driving TFT 20, and a single capacitor 80 is illustrated. However, the type of the OLED display device 100 according to the present exemplary embodiment is not limited thereto. Accordingly, the OLED display device 100 may have various types of structure by including three or more TFTs and two or more capacitors per pixel and further including an additional wiring. As used herein, the term “pixel” refers to a minimum unit for displaying an image, and the display area may represent an image through a plurality of pixels.

The OLED display device 100 according to the first exemplary embodiment may include the first substrate 111, the switching TFT 10, the driving TFT 20, the capacitor 80, and an OLED element 70 which are respectively formed in a plurality of pixels defined in the first substrate 111. The first substrate 111 may further include a gate line 151, and a data line 171 and a common power line 172 which intersect the gate line 151 while being insulated therefrom.

Here, each pixel may be defined by a boundary among the gate line 151, the data line 171, and the common power line 172. However, the definition of the pixel is not limited thereto.

The OLED element 70 may include a first electrode 710, an organic light emitting layer 720 formed on the first electrode 710, and a second electrode 730 formed on the organic light emitting layer 720. Here, since one or more first electrodes 710 may be formed on each pixel, the first substrate 111 may have a plurality of first electrodes 710 which are spaced apart from one another.

In this instance, the first electrode 710 may be an anode, e.g., a hole injection layer (HIL), and the second electrode 730 may be a cathode, e.g., an electron injection layer (EIL). However, the type of the first and second electrodes 710 and 730 is not limited thereto, and the first electrode 710 may be a cathode and the second electrode 730 may be an anode based on a driving method of the OLED display device 100. In addition, the first electrode 710 may be a pixel electrode and the second electrode 730 may be a common electrode.

A hole and an electron injected into the organic light emitting layer 720 are combined with one another to form an exciton. The OLED element 70 may emit light by energy generated when the exciton falls from an excited state to a ground state.

The capacitor 80 may include a pair of sustaining electrodes, i.e., first and second sustaining electrodes 158 and 178, which are disposed to have an insulating layer 160 therebetween. In this instance, the insulating interlayer 160 may be a dielectric material. Capacity of the capacitor 80 may be determined by an amount of electric charges accumulated in the capacitor 80 and a level of a voltage between the first and second sustaining electrodes 158 and 178.

The switching TFT 10 may include a switching semiconductor layer 131, a switching gate electrode 152, a switching source electrode 173, and a switching drain electrode 174. The driving TFT 20 may include a driving semiconductor layer 132, a driving gate electrode 155, a driving source electrode 176, and a driving drain electrode 177.

The switching TFT 10 may be used as a switching element selecting a pixel to emit light. The switching gate electrode 152 may be connected to the gate line 151. The switching source electrode 173 may be connected to the data line 171. The switching drain electrode 174 may be disposed to be spaced apart from the switching source electrode 173 and may be connected to the first sustaining electrode 158.

The driving TFT 20 may apply driving power for emitting the organic light emitting layer 720 of the OLED element 70 within the selected pixel to the first electrode 710. The driving gate electrode 155 may be connected to the first sustaining electrode 158 which is connected to the switching drain electrode 174. The driving source electrode 176 and the second sustaining electrode 178 may be connected to the common power line 172. The driving drain electrode 177 may be connected to the first electrode 710 of the OLED element 70 through a drain contact hole 181.

Due to the configuration of the switching TFT 10 and the driving TFT 20 as described above, the switching TFT 10 may be operated by a gate voltage applied to the gate line 151 to thereby transfer a data voltage applied to the data line 171 to the driving TFT 20. A voltage having a level equal to a difference between a level of a common voltage applied from the common power line 172 to the driving TFT 20 and a level of the data voltage transferred from the switching TFT 10 may be stored in the capacitor 80, and a current having a level equal to the level of the voltage stored in the capacitor 80 may flow into the OLED element 70 through the driving TFT 20, and thereby the OLED element 70 may emit light.

Referring to FIGS. 4 and 5, a structure of the OLED display device 100 according to the first exemplary embodiment will be described further.

Since FIG. 4 illustrates the OLED element 70, the driving TFT 20, the capacitor 80, the data line 171, and the common power line 172, a description thereof will be mainly provided. With regard to the stacked structure of the driving TFT 20 including the driving semiconductor layer 132, the driving gate electrode 155, the driving source electrode 176, and the driving drain electrode 177, which is the same as that of the switching TFT 10 including the switching semiconductor layer 131, the switching gate electrode 152, the switching source electrode 173, and the switching drain electrode 174, a repeated description thereof will be omitted for conciseness.

In the first exemplary embodiment, the first substrate 111 may use an insulating substrate, e.g., formed of glass, quartz, ceramic, plastic, or the like. However, the material forming the first substrate 111 is not limited thereto, and thus the first substrate 111 may use a metal substrate, e.g., formed of stainless steel, or the like.

A buffer layer 120 may be disposed on the first substrate 111. The buffer layer 120 may serve to prevent permeation of impure elements to the first substrate 111 and planarize a surface of the first substrate 111, and may be formed of various materials capable of performing the aforementioned functions. For example, the buffer layer 120 may include at least one of silicon nitride (SiNₓ), SiO₂, and silicon oxynitride (SiOₓN_{y}). However, the buffer layer 120 is not necessarily required, and thus may be omitted based on the type, the process conditions, and the like, of the first substrate 111.

The driving semiconductor layer 132 may be disposed on the buffer layer 120. The driving semiconductor layer 132 may be formed of at least one semiconductor material, e.g., polycrystalline silicon, amorphous silicon, and oxide semiconductor. In addition, the driving semiconductor layer 132 may include an undoped channel region 135, and a source region 136 and a drain region 137 doped with p-type impurities at both sides of the channel region 135, respectively. In this instance, ion materials used for doping may be p-type impurities such as boron (B), e.g., diborane (B₂H₆). Here, such impurities may differ based on the type of the TFT.

A gate insulating layer 140 may be disposed on the driving semiconductor layer 132, the gate insulating layer 140 being formed of, e.g., SiNₓ, SiO₂, or the like. The gate insulating layer 140 may include at least one of, e.g., tetraethyl orthosilicate (TEOS), SiNₓ, and SiO₂. For example, the gate insulating layer 140 may have a double-layer structure in which a SiNₓ layer having a thickness of about 40 nanometers (nm) and a TEOS layer having a thickness of about 80 nm are sequentially stacked. However, the gate insulating layer 140 is not limited to the configuration described in the present exemplary embodiment.

The driving gate electrode 155, the gate line 151 of FIG. 4, and the first sustaining electrode 158 may be formed on the gate insulating layer 140. In this instance, the driving gate electrode 155 may be disposed to overlap at least a portion of the driving semiconductor layer 132, i.e., the channel region 135. The driving gate electrode 155 may serve to block impurities from being doped in the channel region 135 at the time of the impurities being doped in the source region 136 and the drain region 137 of the driving semiconductor layer 132 during the formation of the driving semiconductor layer 132.

The driving gate electrode 155 and the first sustaining electrode 158 may be disposed on the same layer, and may be formed of substantially the same metal. Here, the metal forming the driving gate electrode 155 and the first sustaining electrode 158 may include at least one of, e.g., molybdenum (Mo), chromium (Cr), and tungsten (W). For example, the driving gate electrode 155 and the first sustaining electrode 158 may be formed of Mo or an alloy including Mo.

The insulating layer 160 may be disposed on the gate insulating layer 140, the insulating layer 160 covering the driving gate electrode 155. The insulating layer 160 may be an insulating interlayer. The insulating layer 160 may be formed of, e.g., SiNₓ, SiOₓ, or the like, in a manner similar to that of the gate insulating layer 140. The gate insulating layer 140 and the insulating layer 160 may include respective contact holes through which the source region 136 and the drain region 137 of the driving semiconductor layer 132 are exposed.

The driving source electrode 176, the driving drain electrode 177, the data line 171, the common power line 172, and the second sustaining electrode 178 may be disposed on the insulating layer 160 in the display area DA. The driving source electrode 176 and the driving drain electrode 177 may be connected to the source region 136 and the driving region 137 of the driving semiconductor layer 132 through contact holes, respectively.

In detail, the driving source electrode 176, the driving drain electrode 177, the data line 171, the common power line 172, and the second sustaining electrode 178 may include a refractory metal formed of at least one of Mo, Cr, tantalum (Ta), and titanium (Ti), or an alloy thereof, and may have a multilayer structure including the refractory metal layer and a low-resistance conductive layer. Examples of the multiplayer structure may include a double-layer structure of a Cr or Mo (or an alloy thereof) lower layer and an aluminum (Al) upper layer, and a triple-layer structure of a Mo (or an alloy thereof) lower layer, an Al (or an alloy thereof) intermediate layer, and a Mo (or an alloy thereof) upper layer.

The driving source electrode 176, the driving drain electrode 177, the data line 171, the common power line 172, and the second sustaining electrode 178 may be formed of various materials other than the aforementioned materials.

Accordingly, the driving TFT 20 including the driving semiconductor layer 132, the driving gate electrode 155, the driving source electrode 176, and the driving drain electrode 177 may be formed. However, the configuration of the driving TFT 20 is not limited to the aforementioned example, and may be modified in various manners.

A protective layer 180 may be formed on the insulating interlayer 160 to cover the driving source electrode 176, the driving drain electrode 177, and the like, thereon. The protective layer 180 may be formed of an organic material, e.g., polyacrylate, polyimide, and the like. The protective layer 180 may be a planarization layer. The protective layer 180 may be formed of at least one of, e.g., a polyacrylate resin, an epoxy resin, a phenolic resin, a polyamide resin, a polyimide resin, an unsaturated polyester resin, a polyphenylenether resin, a polyphenylenesulfide resin, and benzocyclobutene (BCB).

The protective layer 180 may include the drain contact hole 181 through which the driving drain electrode 177 is exposed. The first electrode 710 may be disposed on the protective layer 180, and may be connected to the driving drain electrode 177 through the drain contact hole 181 of the protective layer 180.

A pixel defining layer 190 may be disposed on the protective layer 180 to cover the first electrode 710 thereon. The pixel defining layer 190 may include an aperture 199 through which the first electrode 710 is exposed.

That is, the first electrode 710 may be disposed to correspond to the aperture 199 of the pixel defining layer 190. The pixel defining layer 190 may be formed of a resin, e.g., a polyacrylate resin or a polyimide resin.

In addition, the pixel defining layer 190 may be formed of a photosensitive organic material or a photosensitive polymer material. For example, the pixel defining layer 190 may be formed using one of, e.g., polyacrylate, polyimide, photosensitive polyimide (PSPI), photosensitive acryl (PA), a photosensitive novolak resin.

The organic light emitting layer 720 may be disposed on the first electrode 710 within the aperture 199 of the pixel defining layer 190, and the second electrode 730 may be disposed on the pixel defining layer 190 and the organic light emitting layer 720. Accordingly, the OLED element 70 including the first electrode 710, the organic light emitting layer 720, and the second electrode 730 may be formed.

One of the first electrode 710 and the second electrode 730 may be formed using a transparent conductive material, and the other thereof may be formed using a transflective conductive material or a reflective conductive material. The OLED display device 100 may be determined to be a front-emission-type display device, a bottom-emission-type display device, or a double-side emission-type display device based on the type of material forming the first and second electrodes 710 and 730.

For example, in a case in which the OLED display device 100 according to the exemplary embodiment is a front-emission-type display device, the first electrode 710 may be formed of a transflective or reflective conductive material, and the second electrode 730 may be formed of a transparent conductive material.

Examples of the transparent conductive material may include at least one of, e.g., indium-tin oxide (ITO), indium-zinc oxide (IZO), zinc oxide (ZnO), and indium oxide (In₂O₃). Examples of the reflective conductive material may include at least one of lithium (Li), calcium (Ca), lithium fluoride/calcium (LiF/Ca), lithium fluoride/aluminum (LiF/Al), aluminum (Al), silver (Ag), magnesium (Mg), and gold (Au).

The organic light emitting layer 720 may be formed of a low molecular weight organic material or a polymer organic material. The organic light emitting layer 720 may be formed as a multilayer including at least one of a light emitting layer, a hole injection layer (HIL), a hole transporting layer (HTL), an electron transporting layer (ETL), and an electron injection layer (EIL). For example, the HIL may be disposed on the first electrode 710 having a positive pole, and may include the HTL, the light emitting layer, the ETL, and the EIL sequentially stacked thereon.

Although the organic light emitting layer 720 is only formed in the aperture 199 of the pixel defining layer 190 in the first exemplary embodiment, the disposition of the organic light emitting layer 720 is not limited thereto. Accordingly, at least one of the multilayers constituting the organic light emitting layer 720 may be disposed upwardly of the first electrode 710 and between the pixel defining layer 190 and the second electrode 730, within the aperture 199 of the pixel defining layer 190. In detail, the HIL, the HTL, the ETL, and the EIL of the organic light emitting layer 720 may be formed in a portion other than the aperture 199 due to an open mask, and the light emitting layer of the organic light emitting layer 720 may be formed for each aperture 199 through a fine metal mask (FMM).

Meanwhile, in a case in which an LCD device is used as a display device according to an exemplary embodiment, the first electrode 710 may be physically and electrically connected to the driving drain electrode 177 through the drain contact hole 181, and may receive a data voltage applied thereto from the driving drain electrode 177. The first electrode 710 applied by the data voltage thereto may generate an electric field along with the second electrode 730, i.e., the common electrode, to which a common voltage is applied, to thereby determine a direction of liquid crystal molecules of a liquid crystal layer (not illustrated) between the two electrodes, i.e., the first and second electrodes 710 and 730. The first and second electrodes 710 and 730 may constitute a capacitor (hereinafter, referred to as a “liquid crystal capacitor”), and may maintain a voltage applied thereto, even subsequently to the TFT being turned off.

A second substrate 201 may be sealingly attached to the first substrate 111 while having the OLED element 70 therebetween. The second substrate 201 may sealingly encapsulate the switching TFT 10, the driving TFT 20, and the OLED element 70 which are disposed on the first substrate 111 to protect the encapsulated elements from the external environment. In general, the second substrate 201 may use an insulating substrate formed of a material such as glass or plastic. In a case of a front-emission-type display device in which an image is displayed toward the second substrate 201, the second substrate 201 may be formed of a light transmissive material.

Meanwhile, a buffer material 600 may be disposed between the first substrate 111 and the second substrate 201. The buffer material 600 may protect internal elements such as the OLED element 70 against impacts to be applied thereto externally of the OLED display device 100. Further, the buffer material 600 may enhance mechanical reliability of the OLED display device 100. The buffer material 600 may include at least one of an organic sealant, e.g., urethane resin, an epoxy resin, and an acrylic resin, and an inorganic sealant, e.g., silicon. The urethane resin may use, e.g., urethane acrylate. The acrylic resin may use, e.g., butylacrylate or ethylhexylacrylate.

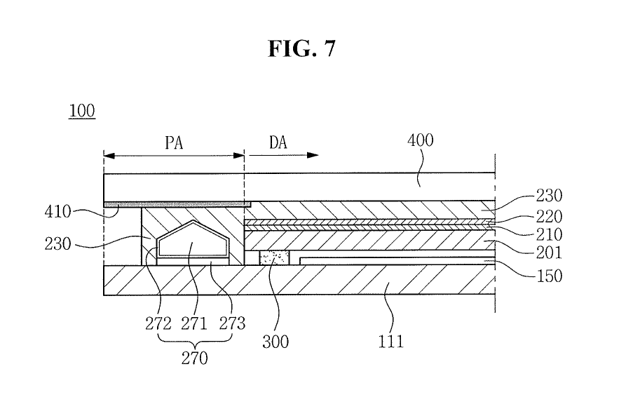

Hereinafter, second and third exemplary embodiments will be described with reference to FIGS. 6 and 7. A description of the same configuration described in the first exemplary embodiment will be omitted for conciseness.

FIG. 6 is a perspective view schematically illustrating an OLED display device according to a second exemplary embodiment. FIG. 7 is a perspective view schematically illustrating an OLED display device according to a third exemplary embodiment.

Referring to FIG. 6, a cross section of a spacer 270 according to the second exemplary embodiment may have a quadrangular shape. Referring to FIG. 7, a cross section of a spacer 270 according to the third exemplary embodiment may have a pentagonal shape. However embodiments are not limited thereto, e.g., the cross section of the spacer 270 may be one of a semi-circular shape or a polygonal shape.

By way of summation and review, a display device commonly has a driving chip or a FPCB in a pad area of a display panel. An adhesive layer for adhering the display panel to a window may be positioned in an empty space between the pad area and the window. However, in the case that the empty space between the pad area and the window is only filled with the first adhesive layer, the driving chip, and the like, may be damaged by external forces applied thereto. Further, in a case in which a spacer having a multilayer film is disposed in the empty space between the pad area and the window, a light shielding film or a polarizing film within the display panel which is pressed by external forces may be damaged due to collision with the spacer, which is relatively rigid.

In contrast, embodiments are directed to a display device capable of increasing resistance to external forces and protecting the driving chip and the polarizing film within a display panel. That is, according to exemplary embodiments, the OLED display device may include a spacer having elasticity in the gap between the pad area of the display panel and the window, thus increasing resistance to external forces and protecting the driving chip. In addition, the OLED display device may prevent damage to various films within the display panel which come in contact with the spacer due to external forces applied thereto.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display device, comprising:
a display panel including a display area and a pad area;
a window opposite to the display panel, the window covering the display area and the pad area of the display panel;
a spacer in the pad area and having elasticity; and
a first adhesive layer between the window and the display panel, the first adhesive layer being on at least a portion of the spacer.

2. The display device as claimed in claim 1, further comprising a circuit member on the pad area.

3. The display device as claimed in claim 2, wherein the spacer is adjacent to at least an end of the circuit member.

4. The display device as claimed in claim 1, wherein a height of the spacer is less than a gap between the pad area and the window.

5. The display device as claimed in claim 1, wherein the spacer includes:
a cushion layer having elasticity; and
a coating layer encapsulating the cushion layer.

6. The display device as claimed in claim 5, wherein the spacer further comprises a second adhesive layer between the display panel and the coating layer.

7. The display device as claimed in claim 5, wherein a hardness of the coating layer is greater than a hardness of the first adhesive layer.

8. The display device as claimed in claim 7, wherein a shore hardness of the coating layer is in a range of about 20 to about 80.

9. The display device as claimed in claim 5, wherein a hardness of the cushion layer is less than a hardness of the first adhesive layer.

10. The display device as claimed in claim 5, wherein a viscosity of the cushion layer is in a range of about one centipoise (cps) to about 100,000 cps.

11. The display device as claimed in claim 5, wherein the coating layer includes silicon rubber.

12. The display device as claimed in claim 5, wherein the cushion layer includes at least one of a silicon gel, a silicon fluid, a silicon resin, and a liquid epoxy resin.

13. The display device as claimed in claim 2, wherein the circuit member is at least one of an integrated circuit chip and a flexible printed circuit board (FPCB).

14. The display device as claimed in claim 1, wherein a cross section of the spacer has one of a semi-circular shape and a polygonal shape.
